(19) United States
(12) Patent Application Publication
(10) Pub. No.: US 2019/0228932 A1
(43) Pub. Date: Jul. 25, 2019

(54) LUMINOUS MEMBRANE KEYBOARD

(71) Applicant: SUZHOU LUUMII LTD., Suzhou City (CN)

(72) Inventor: Yu-Kai LIN, Jiangsu Province (CN)

(21) Appl. No.: 16/029,598

(22) Filed: Jul. 8, 2018

(30) Foreign Application Priority Data
Jan. 24, 2018 (TW) 107201183

(51) Int. Cl. H01H 13/83; H01H 13/705; H01L 33/52; H01L 33/50

(52) U.S. Cl. CPC H01H 13/83; H01H 13/705; H01H 2219/036; H01L 33/507; H01L 33/52

(57) ABSTRACT

A luminous membrane keyboard includes a substrate, a membrane switch assembly, a key, and an LED module. The substrate has a feature hole. The membrane switch assembly is superposed on one side of the substrate. The key is disposed over the substrate and has a key cap cloaking the feature holes. The membrane switch assembly is located between the substrate and the key cap. The LED module includes a circuit board and a micro LED chip disposed on the circuit board corresponding to the key. The circuit board is superposed on another side of the substrate. The micro LED chip is arranged to correspond to the feature holes. Thereby, the volume of a luminous membrane keyboard can be reduced.

### BACKGROUND OF THE INVENTION

### 1. Technical Field

The invention relates to luminous membrane keyboards, particularly to a luminous membrane keyboard with an independent light source corresponding to each key.

### 2. Related Art

Luminous keyboards are the trend of design of current keyboards. Such a keyboard is provided with a backlight for recognition and use in dark environment.

Keyboards for desktop computers are not subject to space, their designs are less restricted by dimensions. However, laptop computers or portable keyboards are subject to limitations on installation space, operation space, and packaged LEDs (light emitting diodes) technologies, it is difficult to design an independent LED to each key. Thus, generally speaking, a keyboard is equipped with a single or a few LEDs and light guide elements to guide lights to all keys. However, the light guide elements still occupy considerable space and can interfere with of other components.

### SUMMARY OF THE INVENTION

The invention provides a luminous membrane keyboard with independent light sources corresponding to each key.

The invention provides a luminous membrane keyboard, which includes a substrate, a membrane switch assembly, a key and an LED module. The substrate has feature holes. The membrane switch assembly is superposed on one side of the substrate. The key is disposed over the substrate and has a key cap covering the feature holes. The membrane switch assembly is located between the substrate and the key cap. The LED module includes a circuit board and a micro LED chip disposed on the circuit board corresponding to the key. The circuit board is superposed on another side of the substrate. The micro LED chip is arranged to correspond to the feature holes.

In the luminous membrane keyboard of the invention, a spacer sheet is superposed between the substrate and the circuit board, and the spacer sheet does not cover the micro LED chip. The micro LED chip is hidden in the feature holes.

In the luminous membrane keyboard of the invention, the circuit board is covered by a flexible film layer which does not cover the micro LED chip. The circuit board is covered by a flexible film layer which completely covers the micro LED chip. The micro LED chip is covered by a chip encapsulation which is formed on the circuit board and completely covers the micro LED chip. The chip encapsulation is covered by a phosphor powder layer which completely covers the chip encapsulation.

In the luminous membrane keyboard of the invention, the micro LED chip does not protrude from a surface of the substrate.

In the luminous membrane keyboard of the invention, the key cap is formed with an actuation block toward the substrate and is spaced with the membrane switch assembly. The actuation block is light-permeable.

In the luminous membrane keyboard of the invention, no light guide element is needed to guide light to the keys, so a volume of the luminous membrane keyboard can be reduced and the backlighting performance of the keys can be more diversified.

### BRIEF DESCRIPTION OF THE INVENTION

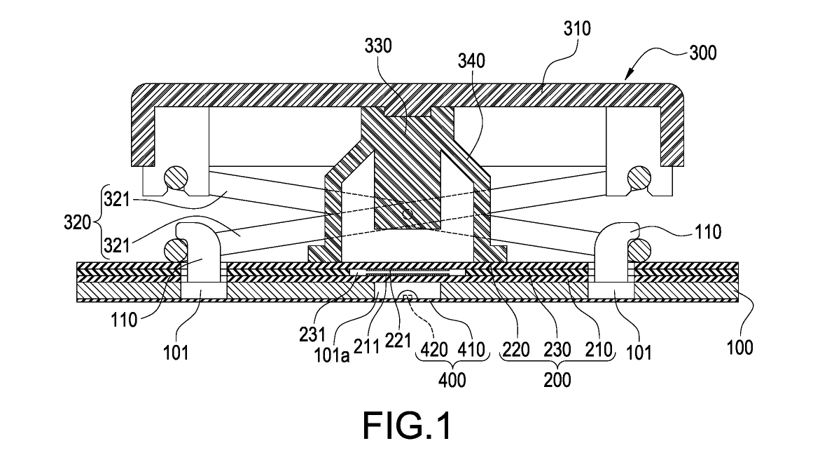

FIG. 1 is a schematic view of luminous membrane keyboard of a preferred embodiment of the invention;

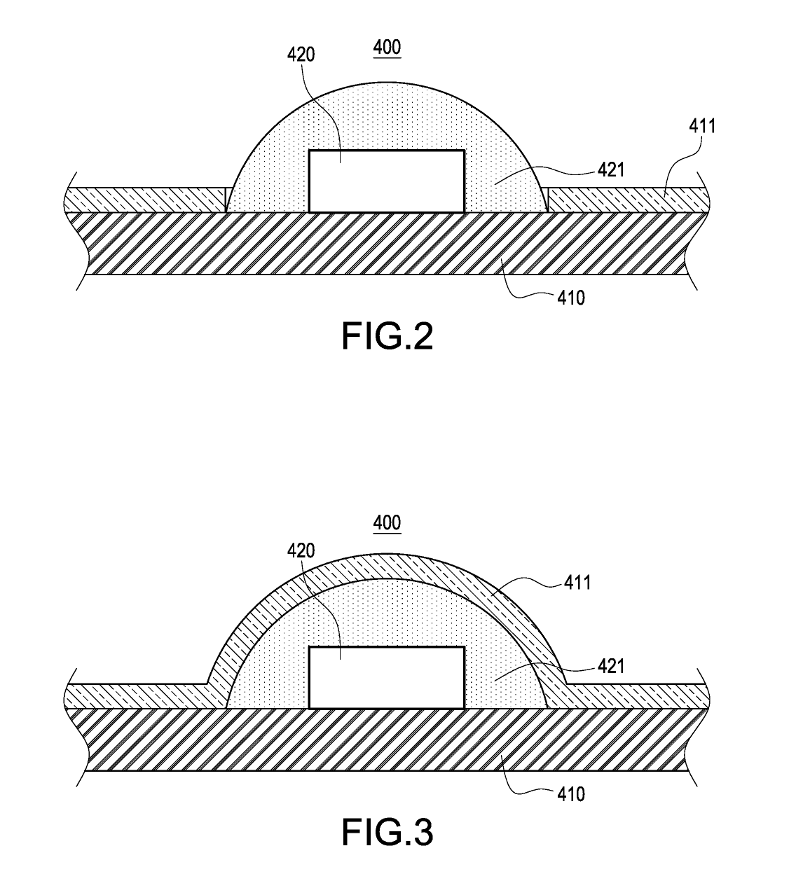

FIG. 2 is a schematic view of the LED module of luminous membrane keyboard of a preferred embodiment of the invention;

FIGS. 3-5 are schematic views of variants of the LED module of luminous membrane keyboard of a preferred embodiment of the invention; and

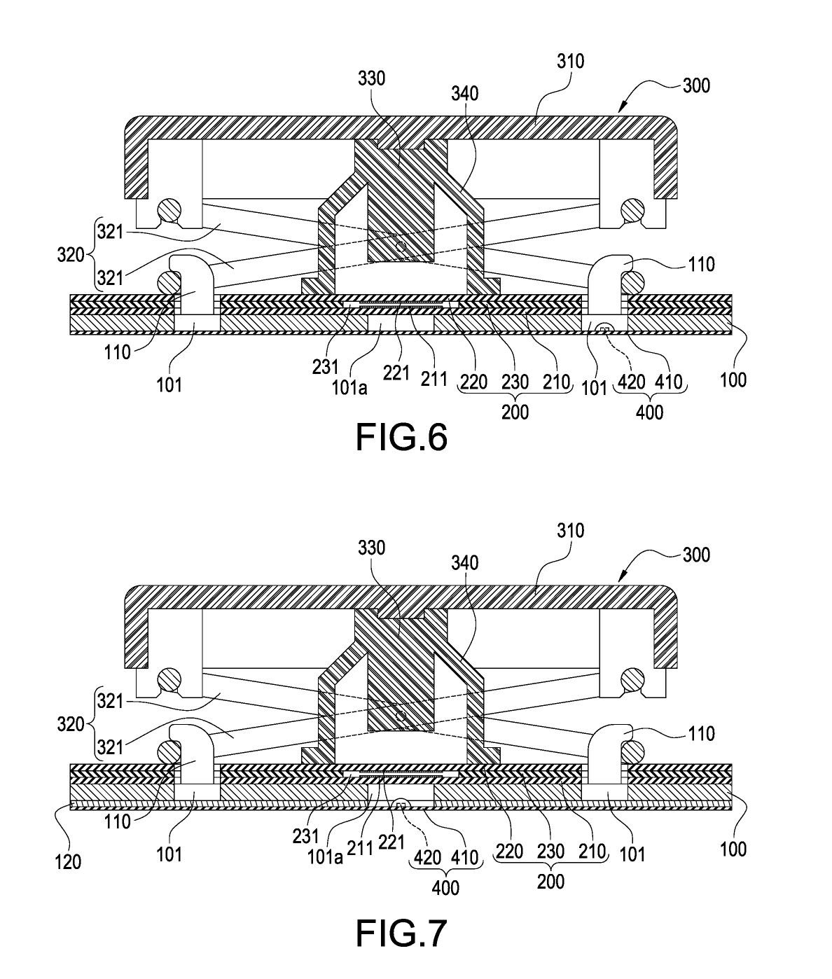

FIGS. 6-7 are schematic views of other arrangements of luminous membrane keyboard of a preferred embodiment of the invention.

### DETAILED DESCRIPTION OF THE INVENTION

Please refer to FIG. 1. A preferred embodiment of the invention provides a luminous membrane keyboard, which includes a substrate 100, a membrane switch assembly 200, at least one key 300 and at least one LED (light emitting diode) module 400.

The substrate 100 is formed with at least one feature hole in this embodiment, the substrate 100 is preferably formed with a plurality of feature holes 101/101a. At least one portion of the feature holes 101 is provided with a hook 110.

The membrane switch assembly 200 is superposed on one side of the substrate 100. The membrane switch assembly 200 includes a first circuit membrane 210, a second circuit membrane 220 and a partition layer 230 between the first circuit membrane 210 and the second circuit membrane 220, which are superposed. The partition layer 230 is formed with an action opening 231 which aligns with the actuation block 330 and the feature holes 101a. The first circuit membrane 210 is provided with a first electrode 211 and the second circuit membrane 220 is provided with a second electrode 221. The first and second electrodes 211, 221 are enclosed in the action opening 231, align with each other and arranged with a separation. The first and second electrodes 211, 221 align with the corresponding feature holes 101a in the substrate 100. Preferably, the luminous membrane keyboard of the invention is covered by a plurality of keys 300. As an example, only one of the keys 300 is described. The key 300 is disposed over the substrate 100 and includes a key cap 310 covering the feature holes 101/101a. The membrane switch assembly 200 is located between the substrate 100 and the key cap 310.

The key 300 includes a scissor support 320 composed of bars 321 pivotally connected to each other. The scissor support 320 includes at least a pair of rods 321 which are crossly pivotally connected. The scissor support 320 separately hooks the key cap 310 and the substrate 100 and is preferably connected to the corresponding feature holes 101 of the substrate 100. Thus, the key cap 310 is fixed to the substrate 100 by the scissor support 320 and the rods 321 can be relatively rotated to allow the key cap 310 to be pressed. In this embodiment, an end of each rod 321 hooks the key cap 310 and the other end thereof hooks the corresponding hook 110 on the substrate 100. The elastic body 340 is formed with an actuation block 330 toward the substrate 100 and is spaced with the membrane switch assembly 200. The actuation block 330 aligns with the first and second electrodes 211, 221. The actuation block 330 is driven to press the membrane switch assembly 200 when the key cap 310 is being pressed so as to electrically conduct the first and second electrodes 211, 221. Preferably, the actuation block 330 may be light-permeable and in this embodiment, the first and second electrodes 211, 221 corresponding to each actuation block 330 and feature holes 101a align axially.

The key cap 310 is provided with an elastic body 340 which connects to the key cap 310 and the membrane switch assembly 200. When the key cap 310 is released, the elastic body 340 can push the key cap 310 away from the membrane switch assembly 200 to restore. Preferably, the elastic body 340 may be light-permeable and integratedly formed with the actuation block 330. In this embodiment, the elastic body 340 is of a cylindrical shape and the actuation block 330 is integrated in the elastic body 340. An end of the elastic body 340 connects to the actuation block 330 and the other end to the membrane switch assembly 200.

Please refer to FIG. 2. The LED module 400 includes a circuit board 410 and a micro LED chip 420 disposed on the circuit board 410. Preferably, each key 300 is disposed with at least one micro LED chip 420. Each micro LED chip 420 may be covered by a light-permeable chip encapsulation 421 to prevent the micro LED chip 420 from being damaged. The circuit board 410 may be covered by a light-permeable flexible film layer 411 (it preferably is made of plastic such as PET, PC, TPU or PMMA) to protect the circuit board 410. As shown in FIG. 3, the flexible film layer 411 may extend to the micro LED chip 420 to cover it.

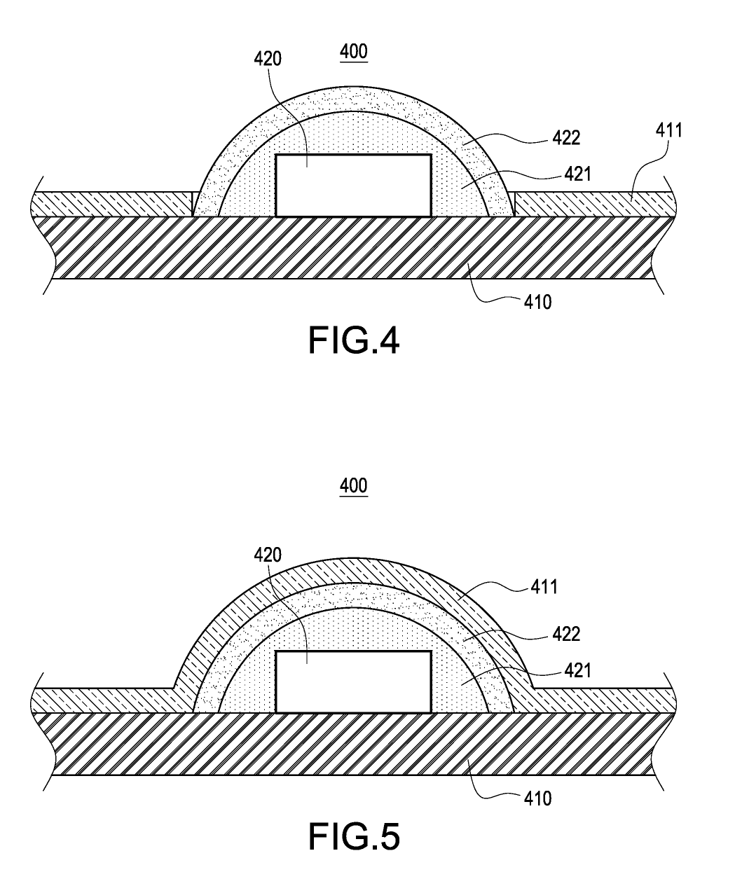

As shown in FIG. 4, the chip encapsulation 421 may be selectively covered by a light-permeable phosphor powder layer 422 composed of resin mixing phosphor powder, which makes the micro LED chip 420 emits light with a specific color. As abovementioned, the circuit board 410 may be covered by a light-permeable flexible film layer 411 to protect it and the flexible film layer 411 may extend to the micro LED chip 420 to cover it.

The circuit board 410 is superposed on another side of the substrate 100. Each micro LED chip 420 is arranged to correspond to one of the feature holes 101/101a. In this embodiment, each micro LED chip 420 is preferably hidden in the corresponding feature holes 101/101a. Each micro LED chip 420 is preferably completely hidden in the feature holes 101/101a without projecting from a surface of the substrate 100.

Please refer to FIG. 1. The micro LED chip 420 may be arranged in the feature holes 101a corresponding to the actuation block 330 of the key 300 so that the light therefrom may pass through the actuation block 330 and the elastic body 340 or be guided to the key cap 310 through the actuation block 330 and the elastic body 340. Please refer to FIG. 6. The micro LED chip 420 may be arranged in the feature holes 101 beside the hook 110 so that the light therefrom may pass through a portion of the key cap 310. the luminous membrane keyboard of the invention, whose single key 300 may also be correspondingly disposed with more than one micro LED chip 420 with different colors so that the key cap 310 may be backlighted with multiple colors.

Each key of the luminous membrane keyboard of the invention is provided with an independent micro LED chip 420, so no light guide element is needed to guide light to the keys 300, a volume of the luminous membrane keyboard can be reduced and the micro LED chip 420 of each key 300 can be activated independently work to make the performance of the luminous membrane keyboard of the invention backlighted diversified.

Please refer to FIG. 7. A spacer sheet 120 may be selectively added between the substrate 100 and the circuit board 410. The invention does not limit a format of the spacer sheet 120. The spacer sheet 120 is used for increasing the distance between the micro LED chip 420 and the membrane switch assembly 200, especially for the actuation block 330 and the corresponding feature holes 101a. The spacer sheet 120 does not cloak the micro LED chip 420 to allow the micro LED chip 420 to emit light through the feature holes 101a, which can be implemented by, but not limited to, holing a spacer sheet 120 with a large area (for example, the same dimension as the substrate 100 or the circuit board 410 in area) at the place corresponding to each micro LED chip 420, or arranging smaller spacer sheets 120 with a small area between two micro LED chips 420. Thus, for the spacer sheet 120 with different thicknesses, the micro LED chip 420 can be hidden in or outside the feature holes 101a. Thereby, once a user presses the key 300 to make the actuation block 330 press the membrane switch assembly 200, the compression does not contact or damage the LEED chip. The arrangement and thickness of the spacer sheet 120 depends on the size of the actuation block 330 and the compression of the elastic body 340. Thus, various circuit boards 410 with different thicknesses are not needed for actuation blocks 330 with different sizes and the elastic bodies 340 with different compression.

It will be appreciated by persons skilled in the art that the above embodiments have been described by way of example only and not in any limitative sense, and that various alterations and modifications are possible without departure from the scope of the disclosed example as defined by the appended claims.

1. A luminous membrane keyboard comprising:
a substrate, having a feature hole;
a membrane switch assembly, superposed on one side of the substrate;
a key, disposed over the substrate, having a key cap covering the feature hole, and the membrane switch assembly being located between the substrate and the key cap; and
a light emitting diode (LED) module, comprising a circuit board and a micro LED chip disposed on the circuit board corresponding to the key, the circuit board being superposed on another side of the substrate, and the micro LED chip being arranged inside the feature hole.

2. The luminous membrane keyboard of claim 1, wherein a spacer sheet is superposed between the substrate and the circuit board, and the spacer sheet does not cover the micro LED chip.

3. The luminous membrane keyboard of claim 1, wherein the micro LED chips is hidden in the feature hole.

4. The luminous membrane keyboard of claim 2, wherein the micro LED chips is hidden in the feature hole.

5. The luminous membrane keyboard of claim 1, wherein the circuit board is covered by a flexible film layer which does not cover the micro LED chip.

6. The luminous membrane keyboard of claim 2, wherein the circuit board is covered by a flexible film layer which completely covers the micro LED chip.

7. The luminous membrane keyboard of claim 1, wherein the micro LED chip is covered by a chip encapsulation that is formed on the circuit board and completely covers the micro LED chip.

8. The luminous membrane keyboard of claim 7, wherein the chip encapsulation is covered by a phosphor powder layer which completely covers the chip encapsulation.

9. The luminous membrane keyboard of claim 1, wherein the micro LED chip does not protrude from a surface of the substrate.

10. The luminous membrane keyboard of claim 1, wherein the key cap has an actuation block extending toward the substrate and is spaced with the membrane switch assembly.

11. The luminous membrane keyboard of claim 10, wherein the actuation block is light-permeable.
